(19) United States
(12) Patent Application Publication
(10) Pub. No.: US 2017/0207180 A1
(43) Pub. Date: Jul. 20, 2017

(54) SEMICONDUCTOR DEVICE

(71) Applicant: UBIQ Semiconductor Corp., Zhubei City (TW)

(72) Inventors: Hiroki Arai, Gunma-ken (JP); Masashi Koyano, Gunma-ken (JP); Nobuyoshi Matsuura, Gunma-ken (JP)

(21) Appl. No.: 15/394,924

(22) Filed: Dec. 30, 2016

(30) Foreign Application Priority Data
Jan. 19, 2016 (JP) 2016-008106

(51) Int. Cl. H01L 23/00; H01L 29/78; H01L 27/088; H01L 23/535

(52) U.S. Cl. CPC H01L 23/562; H01L 24/05; H01L 23/535; H01L 29/7813; H01L 27/088; H01L 24/03; H01L 2224/0401; H01L 2224/03464; H01L 2224/05155; H01L 2224/05144; H01L 2224/05164; H01L 2224/0391; H01L 2924/3511

(57) ABSTRACT

A semiconductor device is disclosed. The semiconductor device includes a semiconductor substrate having an active area and a source electrode formed on the semiconductor substrate. The source electrode is covered by a hard passivation layer and an opening is formed in the hard passivation layer. An under bump metal (UBM) layer used as a barrier film is formed broader than the opening to reduce a spreading resistance during the operation of the semiconductor device and a warp amount of the semiconductor substrate caused by variation of temperature.

### BACKGROUND

1. Technical Field

The present invention relates to a semiconductor device, and more particularly to a semiconductor device in which a plurality of Metal-Oxide-Semiconductor Field-Effect Transistors (MOSFETs) are integrated on a semiconductor substrate.

2. Description of the Related Art

As semiconductor devices have been widely used in various portable devices such as mobile phones, smart phones, notebook computers, and tablet computers, there has been a demand for a compact, thin and light-weight semiconductor device, Chip scale package (Chip Scale Package, CSP) of the semiconductor device.

In a typical wafer-level package, an active region is formed in the vicinity of a surface of a semiconductor device such that an electrode connected to the active region is formed on a semiconductor substrate, and the wafer-level encapsulation body is passed through a solder electrode soldered to the electrode to allow packaging on a package substrate in a Flip-chip manner. In addition, the electrodes formed on the surface of the semiconductor substrate are covered with an under bump metal (UBM). The formation of the metal layer under the bump can not only effectively inhibit the reaction between the aluminum electrode and solder, but also improve the solder wettability.

Please refer to FIG. 10 (see Patent Document 1: Japanese Unexamined Patent Application Publication No. 2002-313833). FIG. 10 shows a package structure having the under bump metal layer described above. In the package structure 100, an inert layer and a bonding pad 102 are formed on the wafer 101, and the bonding pad 102 electrically connects to the active region (not shown) of the wafer 101. In this embodiment, the inert layer is covered by the stress buffer layer 105 and the bonding pad 102 is covered by the under bump metal layer 104 and the under bump metal layer 104 is exposed from the opening portion of the stress buffer layer 105. As a result, a bump 106 made of solder is soldered to the under bump metal layer 104.

In addition, also refer to FIG. 11 (see Patent Document 2: Japanese Patent Application Laid-Open Publication No. 2008-218524). FIG. 11 illustrates a semiconductor device 110 in which a plurality of ferrimagnet transistors are formed may be used as the packaging mentioned above.

In the semiconductor device 110, the semiconductor substrate 111 is formed with gold-oxide field effect transistors 112 to 113, source electrodes 114 and 116, and gate electrodes 115 and 117, respectively. The source electrode 114 and the gate electrode 115 are connected to the field oxide semiconductor 112, and the source electrode 116 and the gate electrode 117 are connected to the field oxide semiconductor 113.

The drain electrode 118 is formed under the semiconductor substrate 111, and the drain electrode 118 is connected to the drain region of the gold oxide half-field effect transistor 112 and the drain region of the gold oxide half-field effect transistor 113, respectively.

However, when the semiconductor device described in the above-mentioned patent document is put into operation, it is likely to encounter a problem that the spreading resistance is not easily reduced.

More specifically, referring to FIG. 11, when the semiconductor device 110 is operated, a current that flows through the semiconductor field 111 integrated in the semiconductor substrate 111 through the gold oxide half-field effect transistors 112 to 113 can also be made to pass through the source electrodes 114 and 116. However, since the cross-sectional areas of the source electrodes 114 and 116 in the direction of the current flow cannot be increased, the spreading resistance cannot be effectively reduced.

In addition, since the semiconductor substrate 111 is formed almost entirely on the lower surface of the semiconductor substrate 111, the upper surface and the lower surface of the semiconductor substrate 111 are formed by only a part of the region forming the source electrode 114. The semiconductor substrate 110 is likely to cause noticeable warping when the semiconductor device 110 is affected by a temperature change.

Although the opening of the source electrode and the gate electrode is left above the semiconductor substrate 111 and covered with a passivation film formed by a resin, heating and thickening the passivation film also causes the heating time of the substrate 111 to become long, and therefore the semiconductor substrate 111 is subject to a large thermal stress which generates a large amount of warping.

### SUMMARY

In view of the above, the present invention provides a semiconductor device capable of effectively solving the above-described problems encountered in the prior art by reducing the amount of warping of the semiconductor substrate when the temperature of the semiconductor substrate is changed.

According to an embodiment of the invention, a semiconductor device is provided. In this embodiment, the semiconductor device includes a semiconductor substrate, an electrode, a barrier film, an insulating layer, and an opening. The semiconductor substrate is formed with an active area. The electrode is formed on the first surface side of the semiconductor substrate. The barrier film covers the electrodes. The insulating layer is formed on the first surface side of the semiconductor substrate and covers the electrode. The opening is formed by using an insulating layer covering the electrode as an opening, wherein a peripheral edge portion of the barrier film is disposed outside the peripheral edge portion of the opening portion.

Another embodiment according to the present invention is also a semiconductor device. In this embodiment, the semiconductor device includes a semiconductor substrate, a first gate electrode, a second gate electrode, a first source electrode, a second source electrode, a barrier film, a common drain electrode, an insulating layer, and an opening. The semiconductor substrate is formed with a first transistor and a second transistor. The first gate electrode and the second gate electrode are formed on the first surface side of the semiconductor substrate. The first source electrode and the second source electrode are formed on the first surface side of the semiconductor substrate. The barrier film covers the first source electrode and the second source electrode. The common drain electrode is formed on the second surface side of the semiconductor substrate. The insulating layer is formed on the first surface side of the semiconductor substrate and covers the first source electrode and the second source electrode. The opening is formed by using the insulating layer covering the first source electrode and the second source electrode as an opening, wherein a peripheral edge of the barrier film is disposed outside the peripheral edge of the opening portion.

In one embodiment of the present invention, the insulating layer includes an inorganic insulating film covering the first surface side of the semiconductor substrate and a resin insulating film covering the inorganic insulating film. The inorganic insulating film covers the first source electrode and the second source electrode, and has an exposed opening. The barrier film is formed on the first source electrode and the second source electrode exposed at the exposed opening. The resin insulating film covers the first source electrode and the second source electrode, and is formed with an opening.

In one embodiment of the present invention, the common drain electrode is covered with a metal film, and the metal film is made of the same kind of metal as the barrier film.

In one embodiment of the present invention, the first source electrode is formed so as to surround the first gate electrode and the second source electrode is formed so as to surround the second gate electrode.

In one embodiment of the present invention, the insulating layer is formed by an inorganic insulating film or a resin insulating film.

Compared with the prior art, the semiconductor device of the present invention has the following technical features and specific effects:

(1) It is possible to increase the area of the barrier film by arranging the peripheral edge of the barrier film more outwardly than the peripheral edge of the opening portion, and not only to reduce the spreading resistance of the respective electrodes. The amount of metal on the first surface side of the semiconductor substrate is increased and the difference between the amounts of the metal on the second surface side covered by the common drain electrode can be reduced. Therefore, the amount of metal formed on the front surface and the back surface of the semiconductor substrate can effectively reduce the amount of warping to the semiconductor substrate when it is affected by temperature change.

(2) The position and size of the barrier film can be determined by the opening formed in the inorganic insulating film, and the size of the solder electrode adhered to the barrier film may be determined by the opening portion formed in the resin insulating film.

(3) The common drain electrode may be covered by a metal film formed by the same kind of metal as the barrier film, thereby increasing the overall thickness of the common drain electrode to reduce the common resistance of the common drain electrode.

(4) The first source electrode and the second source electrode may be formed by surrounding the first gate electrode and the second gate electrode, respectively, and area of the first source electrode and the second source electrode is increased in order to reduce the spreading resistance of the semiconductor device during operation.

(5) The source electrode may be covered only by an insulating layer made of an inorganic insulating film or a resin insulating film, so that the number of components of the semiconductor device and the manufacturing steps can be reduced.

### BRIEF DESCRIPTION OF THE DRAWINGS

FIG. 1A to 1C show a preferred embodiment of a semiconductor device according to the present invention, wherein FIG. 1A is a plan view of a semiconductor device;

FIG. 1B is a plan view of an electrode formed in a semiconductor device;

FIG. 1C is a cross-sectional view of a semiconductor device;

FIGS. 2A and 2B are plan views illustrating other configurations of the electrode;

FIG. 3A is an enlarged cross-sectional view of a semiconductor device according to the present invention;

FIG. 3B is a circuit diagram showing a case where the semiconductor device is used as a protection circuit;

FIGS. 4A to 4D are cross-sectional views corresponding to respective manufacturing steps of the semiconductor device;

FIG. 5 is a cross-sectional view showing another preferred embodiment of the semiconductor device of the present invention;

FIGS. 6A to 6D are cross-sectional views corresponding to respective manufacturing steps of the semiconductor device;

FIG. 7 is a cross-sectional view showing another preferred embodiment of the semiconductor device of the present invention;

FIGS. 8A to 8C are cross-sectional views corresponding to respective manufacturing steps of the semiconductor device;

FIG. 9 is a cross-sectional view showing another preferred embodiment of the semiconductor device of the present invention;

FIG. 10 is a cross-sectional view of a semiconductor device according to the prior art (Patent Document 1);

FIG. 11 is a cross-sectional view of a semiconductor device according to another prior art (Patent Document 2).

### DETAILED DESCRIPTION OF THE PREFERRED EMBODIMENT

Hereinafter, a semiconductor device according to a preferred embodiment of the present invention will be described in detail based on the drawings. In the following description, the same reference numerals will be used for like components, and redundant descriptions of parts thereof will be omitted.

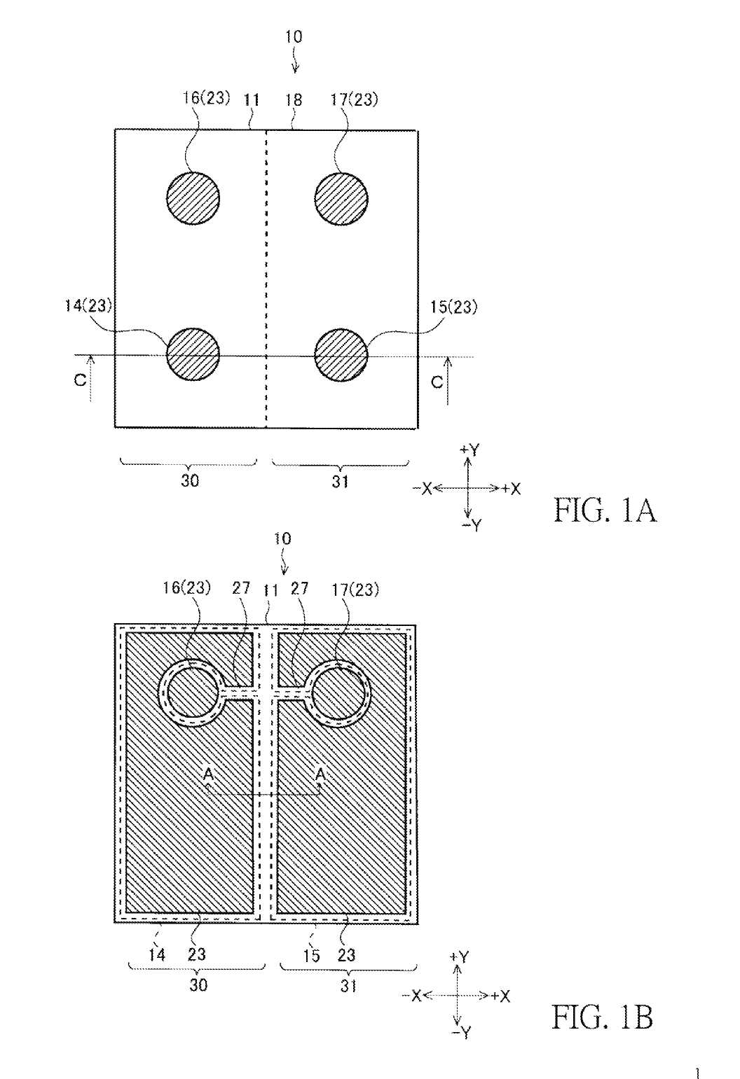

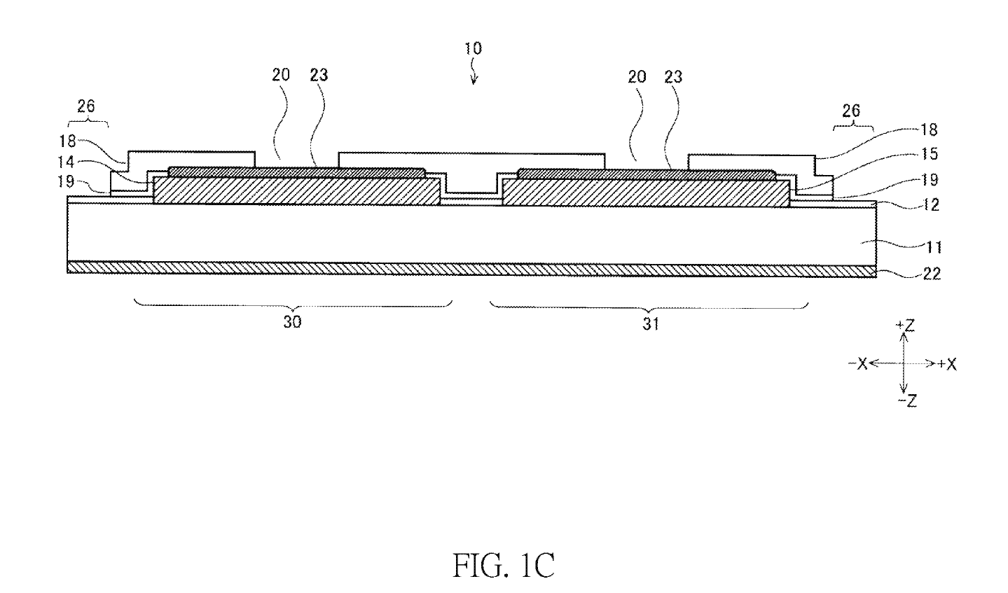

Please refer to FIGS. 1A to 1C. FIG. 1A illustrates a top view of the semiconductor device 10, and FIG. 1B shows a top view of the respective electrode structures formed in the semiconductor device 10. FIG. 1C shows a cross section taken along the CC line in FIG. 1A.

As shown in FIG. 1A, the semiconductor device 10 is a small-sized semiconductor device using a Wafer Level Package (WLP), and a plurality of electrodes connected to an active area formed on the semiconductor substrate 11. The semiconductor substrate 11 has a rectangular shape in which the side length in the Y direction is longer than the side length in the X direction. A first transistor 30 is formed on the −X side in comparison with the center line shown by the broken line, and a second transistor 31 is formed on the +X side. In practical applications, the first transistor 30 and the second transistor 31 may be, but are not limited to, a gold-oxygen half-field effect transistor, wherein the thickness of the semiconductor substrate 11 may be in the range of 50 μm to 200 μm (but not limited by this).

As shown in FIG. 1B, a source electrode 14 and a gate electrode 16 are formed in an area where the first transistor 30 is formed on a first main surface of the semiconductor substrate 11. A periphery edge portion of the source electrode 14 is indicated by a dotted line. A slightly circular gate electrode 16 is formed on the +Y side of the semiconductor substrate 11. The source electrode 14 is formed on the −X side of the semiconductor substrate 11 so as to be surrounding the gate electrode 16, whereas it is almost entirely covering it. In addition, a portion of the source electrode 14 is cut to form a slit 27 for wiring the gate electrode 16 and the semiconductor substrate 11 in a layout. In the present embodiment, although the source electrode 14 is almost entirely covered with an under bump metal (UBM) layer 23 acting as a barrier film, a periphery edge of the under bump metal layer 23 may be disposed at a slightly inner position than a periphery edge of the source electrode 14.

Similarly, in the region of the second transistor 31, a substantially circular gate electrode 17 is formed on the +Y side of the semiconductor substrate 11. The source electrode 15 is formed on the −X side of the semiconductor substrate 11 in such a manner as to surround the gate electrode 17. In the same way as the case of the source electrode 14, the under bump metal layer 23 covers the source electrode 15 almost entirely.

In this embodiment, the upper surfaces of the respective electrodes are covered by the under bump metal layer 23. In other words, almost all of the upper surfaces of the gate electrodes 16 to 17 and the source electrodes 14 to 15 are covered by the under bump metal layer 23. In practice, the film thickness of the gate electrodes 16 to 17 and the source electrodes 14 to 15 may be in the ranges of 3 μm to 5 μm, but not limited thereto.

As shown in FIG. 1C, within the semiconductor device 10, a first transistor 30 and a second transistor 31 are integrated on a semiconductor substrate 11 formed by a semiconductor material (e.g., silicon). The semiconductor substrate 11 is covered with an oxide film 12 formed by, for example, silicon dioxide. In addition, the source electrode 14 is connected to a source region of the first transistor 30 and the source electrode 15 is connected to the source region of the second transistor 31 on the semiconductor substrate 11. In practice, the film thickness of the oxide film 12 may be in the ranges of 0.5 μm to 1 μm, but not limited thereto.

The upper peripheral portion of the oxide film 12 and the source electrode 14 is covered with a hard passivation layer 19 formed by, for example, silicon nitride (Si3N4). In other words, an exposed opening of the hard passivation layer 19 may be formed on the upper surface of the source electrode 14, and the under bump metal layer 23 may be formed by electroless plating using the exposed opening as a mask. Likewise, the upper peripheral portion of the source electrode 15 may be covered with the hard passivation layer 19. In practice, the film thickness of the hard passivation layer 19 may be in the range of 1 μm to 2 μm, but is not limited thereto.

The under bump metal layer 23 is formed as a metallic film on the source electrode 14, and is formed for example of nickel (Ni)/gold (Au), nickel (Ni)/palladium (Pd)/gold (Au). By covering the bump metal layer 23 on to the source electrode 14, a solder electrode (not shown) can be connected to the under bump metal layer 23 without having to connect to the source electrode 14 that uses aluminum as the main material. The semiconductor device 10 is packaged on the package substrate, so that reactions between the source electrode 14 and the solder can be suppressed. That is, the bump lower metal layer 23 is a barrier film for protecting the source electrode 14 from a welding electrode (not shown). Similarly, the source electrode 15 is also covered by the under bump metal layer 23. In practical applications, the film thickness of the under bump metal layer 23 may be in the range of 1 μm to 10 μm, but is not limited thereto.

In addition, the under bump metal layer 23 also covers on top of the gate electrodes 16 to 17 so that the top surface of the gate electrodes 16 to 17 is not exposed to the outside.

The semiconductor substrate 11 is covered with a passivation layer 18 formed by, for example, a resin insulating film such as polyimide. The passivation layer 18 serves to protect the oxide film 12, the hard passivation layer 19, and the under bump metal layer 23 formed on the semiconductor substrate 11. In addition, an opening portion 20 is formed by the passivation layer 18 above the bump lower metal layer 23 to form a substantially circular opening 20. The under bump metal layer 23 covering the source electrodes 14 to 15 may be partially exposed from the opening portion 20, and the solder electrode may be soldered to the under bump metal layer 23 exposed from the opening portion 20. The opening 20 may serve as a mask that defines the shape of a solder electrode. In practice, the film thickness of the passivation layer 18 may be in the range of 1 μm to 10 μm, but is not limited thereto.

In the present embodiment, the insulation layer for protecting the upper surface of the semiconductor substrate 11 includes the passivation layer 18 made of a resin insulating film and a hard passivation layer 19 made of an inorganic insulating film.

The lower surface of the semiconductor substrate 11 may be entirely covered with, for example, a back electrode 22 made of aluminum. The back electrode 22 is a common drain electrode that is simultaneously connected to a drain region of the first transistor 30 of the semiconductor substrate 11 and to a drain region of the second transistor 31. In practice, the thickness of the back electrode 22 may be in the range of 1 μm to 50 μm, but is not limited thereto.

A cutting region 26 for removing the hard passivation layer 19 and the passivation layer 18 is formed on the upper peripheral surface of the semiconductor substrate 11. The oxide film 12 covering the semiconductor substrate 11 is exposed in the cutting region 26. By this manner, the cutting step in the manufacturing step of the semiconductor device can protect the elements constituting the semiconductor device by forming the cut region 26 at the periphery of the upper surface of the semiconductor substrate 11.

As shown in FIG. 1C, in the present embodiment, by allowing the area of the bump metal layer 23 covering the source electrode 14 to be larger than the area of the opening portion 20 of the passivation layer 18, dispersion resistance when the semiconductor device 10 is in operation may be decreased.

In general, the main purpose of forming the under bump metal layer 23 is to prevent the solder electrode from coming into contact with the source electrode 14. Therefore, if only the above-mentioned objective is taken into consideration, the under bump metal layer 23 only needs to cover the area of the opening portion 20. However, in this embodiment, the under bump metal layer 23 covering the source electrode 14 is not formed only on the inner side of the opening 20, but is formed ending on the outer side of the opening 20. In other words, the outer periphery of the under bump metal layer 23 is disposed between the peripheral edge portion of the opening 20 and the peripheral edge portion of the source electrode 14.

Through this structure, the contact area of the under bump metal layer 23 formed by nickel-based conductive material and the source electrode 14 below it may be increased. When the semiconductor device is operated, in addition to the current flowing out through the source electrode 14, current flow can also simultaneously pass through the under bump metal layer 23 such that the cross-sectional area of the current path can be increased and the spreading resistance can be reduced.

The under bump metal layer 23 in this embodiment is formed over almost the entire area of the source electrode 14 in comparison with the case where only the under bump metal layer 23 is formed in the opening portion 20, such that the area of the under bump metal layer 23 used for current path during operation of the semiconductor device can be increased. In this manner, significant effects in reduction of the spreading resistance may be achieved.

As shown in FIG. 1B, on the semiconductor substrate 11, excluding the area of the gate electrodes 16 to 17, the rest of the areas are almost entirely formed by the source electrodes 14 to 15, wherein on top of the source electrodes 14 to 15 are almost entirely formed by the under bump metal layer 23. Therefore, increasing the area of the source electrodes 14 to 15 contributes to reducing the spreading resistance.

In addition, by broadening the area of the under bump metal layer 23, the warp amount of the semiconductor device 10 due to the temperature change can be reduced. More specifically, only a part of the semiconductor device 10 is formed with the source electrodes 14 to 15 and the gate electrodes 16 to 17, respectively. That is to say, not all of the front surface of the semiconductor substrate 11 is covered with the metal film, but only a part of the area is covered with the above-described electrode. Conversely, the back surface of the semiconductor substrate 11 is completely covered by the back electrode 22, which will cause a difference in the amount of metal between the front and back surfaces of the semiconductor substrate 11. When the semiconductor device 10 is affected by temperature change, the amount of warping to the semiconductor device 10 becomes larger. Therefore, since the source electrodes 14 to 15 in this embodiment are almost entirely covered by the under bump metal layer 23, the amount of the metal formed on the front surface of the semiconductor substrate 11 can be increased such that warping due to temperature variations can be effectively reduced.

Furthermore, in the present embodiment, the thickness of the passivation layer 18 can be further reduced. In particular, since the opening 20 of the passivation layer 18 is not used as a mask for forming the under bump metal layer 23, the passivation layer 18 only needs to protect the various electrodes formed on the semiconductor substrate 11. Therefore, the thickness of the passivation layer 18 covering the under bump metal layer 23 can be further reduced. In the embodiment, since the passivation layer 18 is formed by applying a liquid resin to the semiconductor substrate 11 and then heat hardened, by reducing the thickness of the passivation layer 18, the time needed during the step of heat treatment may be reduced and thus the thermal stress experienced by the passivation layer 18 can also be reduced and result in decreased warping of the semiconductor wafer.

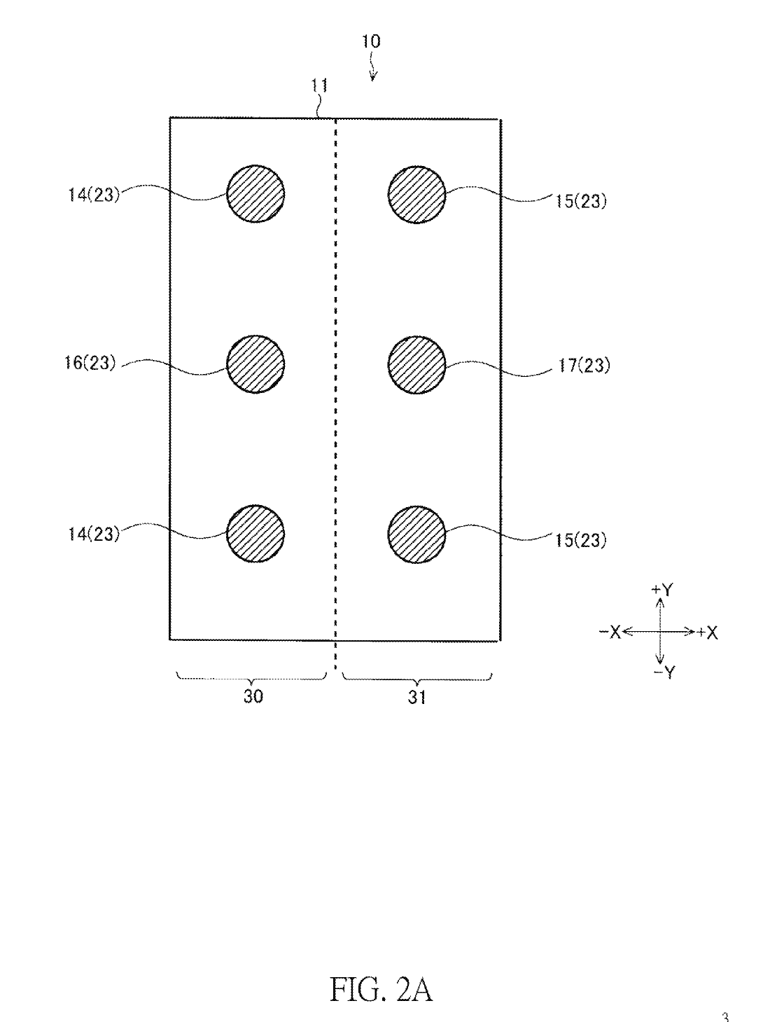

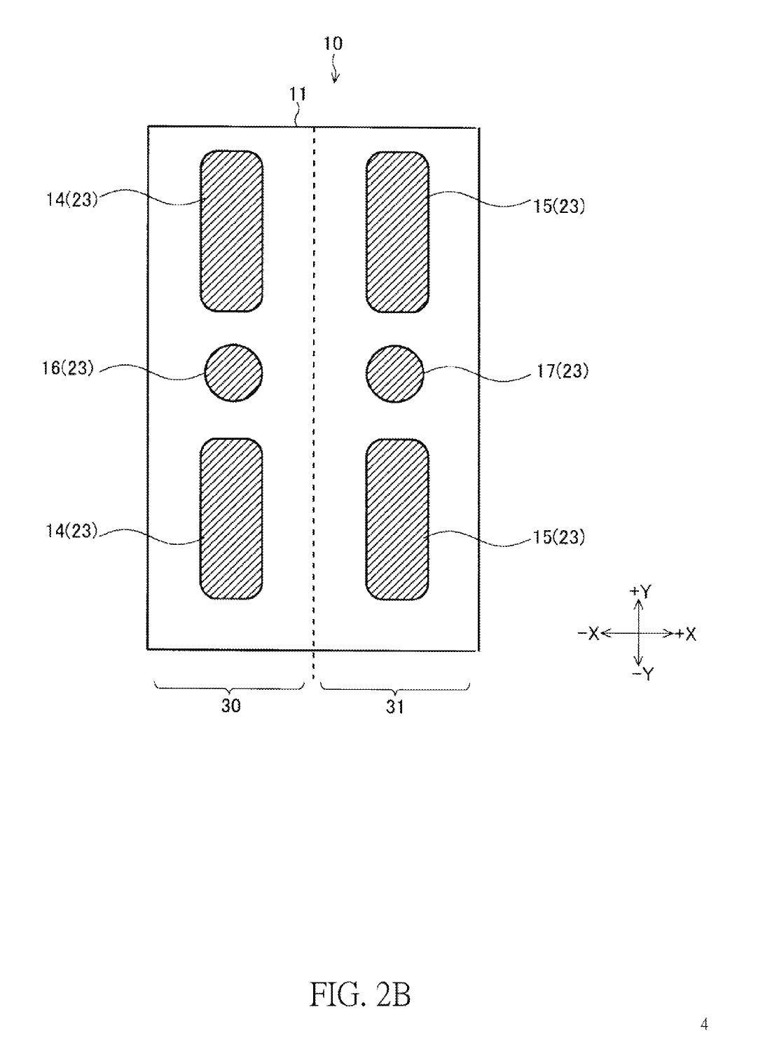

Please refer to FIGS. 2A and 2B. FIG. 2A and FIG. 2B are plane views showing other configurations of the electrode.

As shown in FIG. 2A, six electrodes are formed on the semiconductor substrate 11 in total. Specifically, in the first transistor 30, the gate electrode 16 is exposed at an intermediate portion in the Y direction, and the two source electrodes 14 are exposed at an end in the +Y direction and at an end on the side of the −Y side. Similarly, in the second transistor 31, the gate electrode 17 is exposed at an intermediate portion in the Y-direction, and the two source electrodes 15 are exposed at the ends in the +Y direction and the −Y side.

Since the semiconductor device 10 shown in FIG. 2A exposes a large number of electrode parts, the semiconductor device 10 can be packaged in a package substrate by soldering electrodes soldered to the electrodes. Not only can the spreading resistance of the source electrodes 14 to 15 be reduced, the process of packaging can be executed in a more stable manner.

Also referring to FIG. 2B, similarly, the semiconductor device 10 has a total of six exposed electrodes, but the source electrodes 14 to 15 are not circular in shape, wherein they have a slightly rectangular shape having a long side in the Y direction. As a result, the source electrodes 14 to 15 can be exposed to a large area, and a large amount of solder can be soldered to the chip packaging. Therefore, the semiconductor device 10 can be packaged more stably. In addition, when the semiconductor device 10 is packaged in a package substrate, it is not necessary to fill the underfill between the semiconductor device 10 and the package substrate. In this manner, the cost can also be reduced.

Although the gate electrodes 16 to 17 shown in FIG. 2B are arranged in the center in the Y direction, the gate electrodes 16 to 17 may be arranged on the +Y side or the −Y side without any particular limitation.

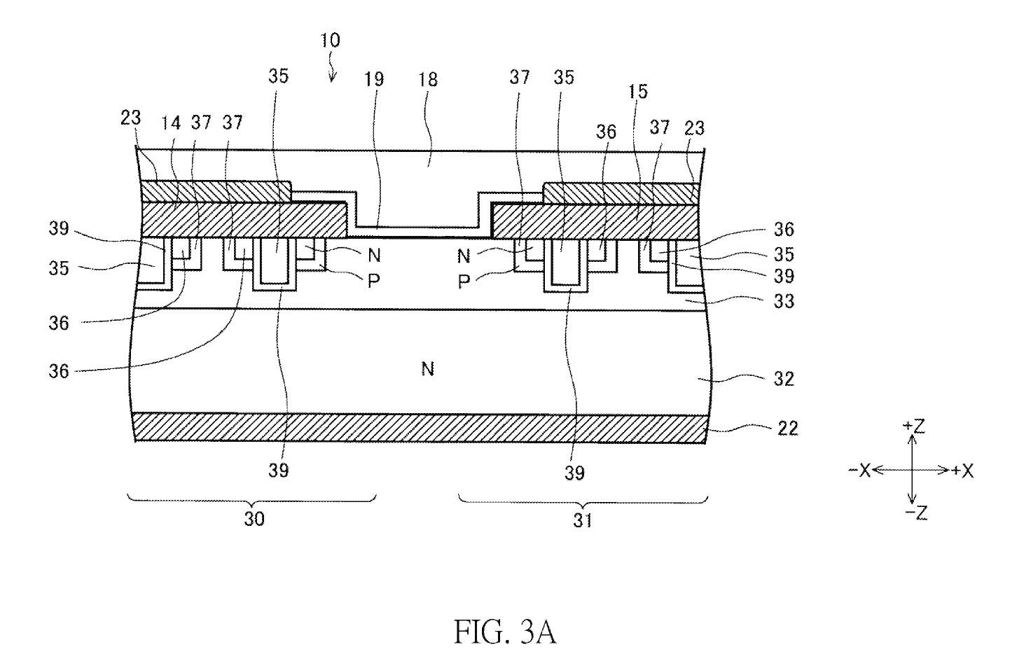

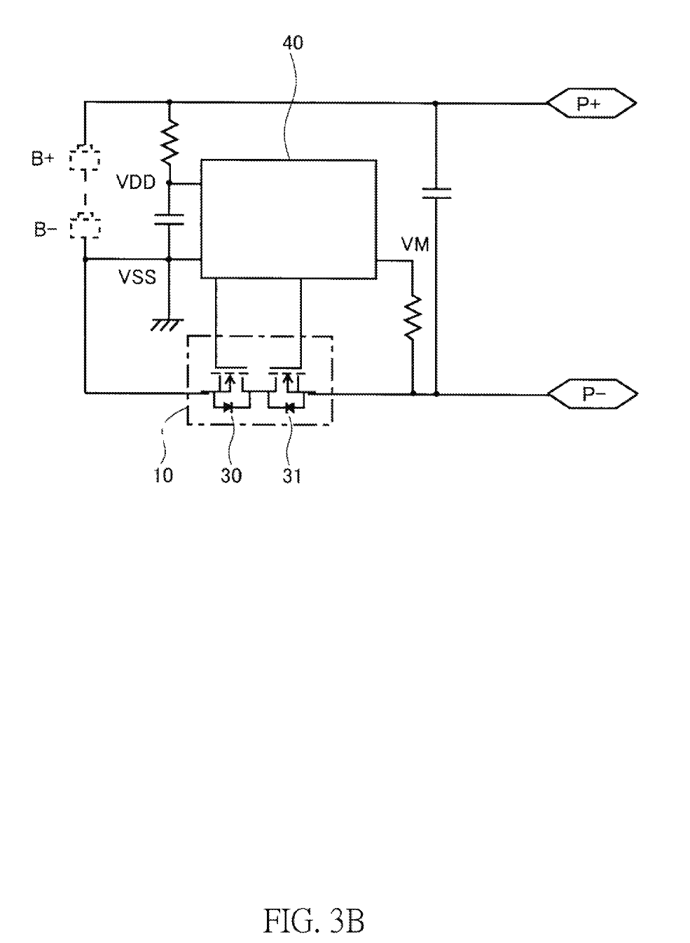

Please refer to FIGS. 3A and 3B. FIG. 3A is a sectional view taken along the line A-A in FIG. 1B, and FIG. 3B is a circuit diagram of a protection circuit of a mobile device.

As shown in FIG. 3A, an N-type epitaxial layer 33 is formed on the front side of the N-type semiconductor substrate 32, for example, and the first and second semiconductor layers 32 and 33 are formed on the semiconductor substrate. The first transistor 30 and the second transistor 31 are electrically insulated from each other by a defined distance in the central region of the semiconductor device 10. In this case, a common drain electrode 22 is formed on the back surface side of the semiconductor substrate 32.

In the epitaxial layer 33, a plurality of P-type gate regions 37 are formed and an N-type source region 36 is formed in the gate region 37. Next, in the gate region 37, a trench is formed and a gate oxide film 39 and a gate electrode 35 are sequentially formed in the trench to form a plurality of cells in the epitaxial layer 33 having the above-described configuration. Above the epitaxial layer 33, a hard passivation layer 19 and a passivation layer 18 such as a silicon nitride film can be formed as an insulating film.

In addition, source electrodes 14 to 15 and gate electrodes 16 to 17 (not shown) are also formed on top of the epitaxial layer 33.

In terms of the under bump metal layer 23, the under bump metal layer 23 covers the exposed source electrodes 14 to 15 and the gate electrodes 16 to 17 (not shown).

FIG. 3B illustrates a protection circuit of a mobile device using the semiconductor device 10 of the present embodiment. In practice, a mobile device can be a foldable mobile phone or a smart phone, but not limited thereto. As shown in FIG. 3B, the terminals P+ and P− denote electrodes connected to the positive electrode and the negative electrode provided in the mobile device frame (not shown). Terminals B+ and B− denote connections the positive electrode and negative electrode of a secondary battery (not shown).

As described above, the semiconductor device 10 of the present embodiment has the first transistor 30 and the second transistor 31, and the gate electrodes of the first transistor 30 and the second transistor 31 are connected to the output side terminal of the control IC 40. In addition, the source electrode of the first transistor 30 is connected to the terminal B−, and the source electrode of the second transistor 31 is connected to the terminal P−.

In the present embodiment, as shown in FIG. 1C, since the under bump metal layer 23 broadly covers the source electrodes 15 to 16, the spreading resistance of the source electrodes 15 to 16 can be reduced. As a result, the power consumption of the mobile device provided with the semiconductor device 10 can be reduced, and the power consumption of the secondary battery can also be reduced.

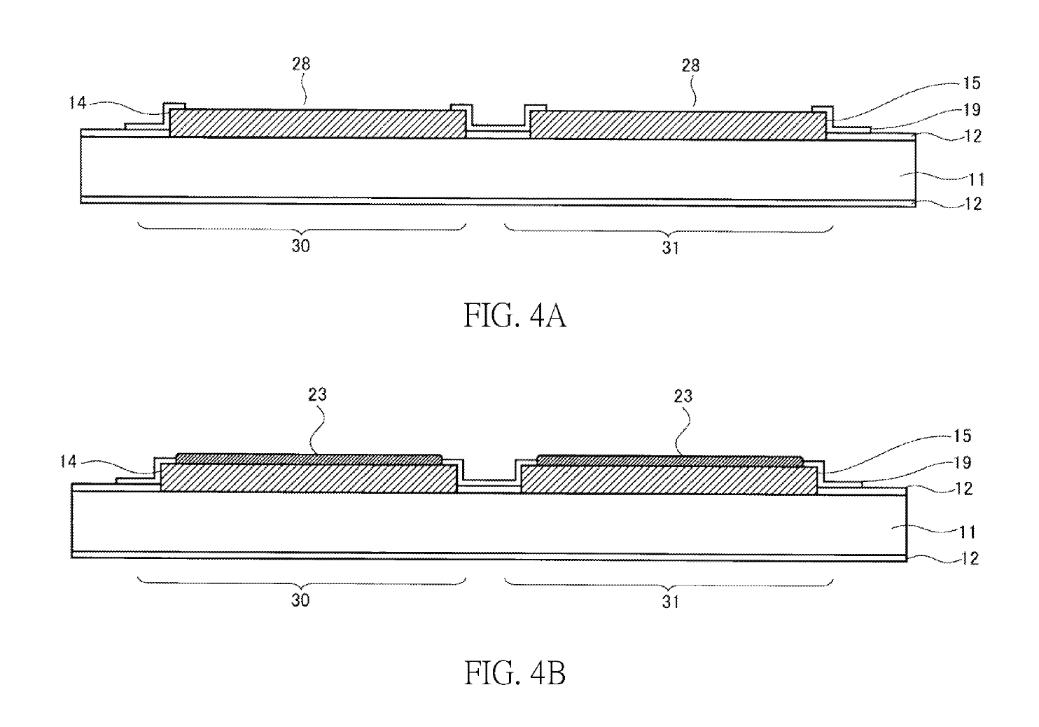

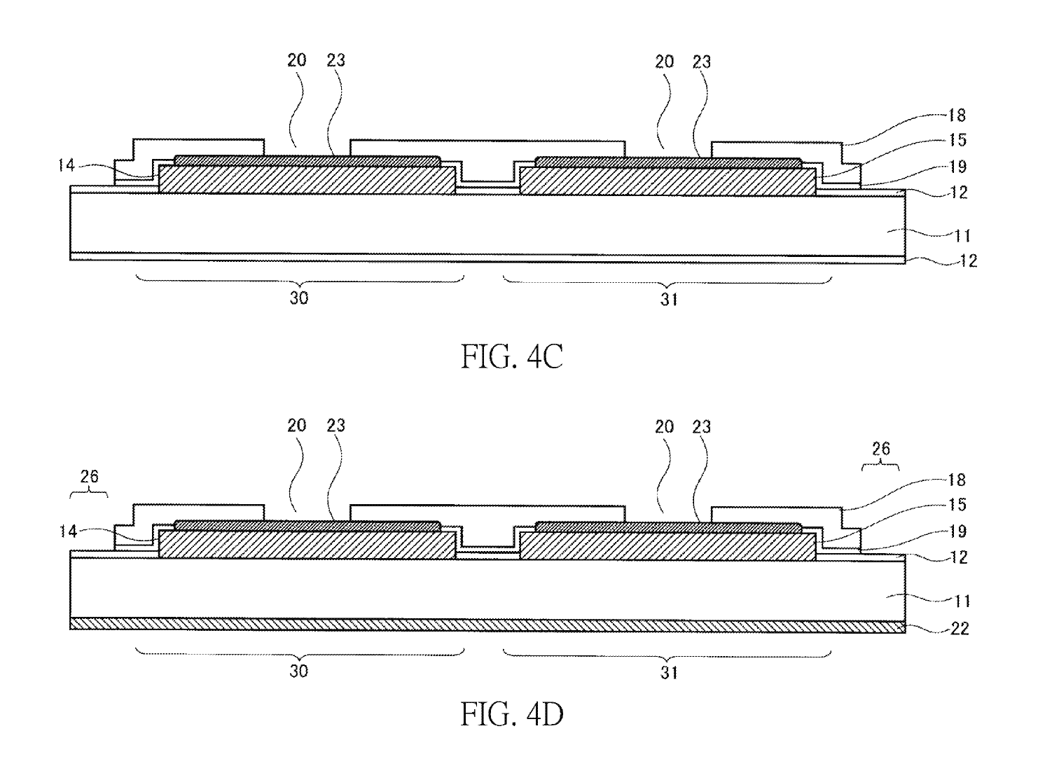

Please refer to FIGS. 4A to 4D. FIG. 4A to 4D are cross-sectional view of each manufacturing step corresponding to the manufacturing method of the semiconductor device described in order.

As shown in FIG. 4A, firstly, a semiconductor substrate 11 is provided and a first transistor 30 and a second transistor 31 as shown in FIG. 3A, for example, are formed on a semiconductor substrate 11 using known diffusion techniques. Then, source electrodes 14 to 15 made of aluminum or an aluminum alloy are formed on the semiconductor substrate 11 by removing a part of the oxide film covering the semiconductor substrate 11 by known photolithography technique and by a film forming technique such as electroless plating. Then, for example, silicon nitride (Si3N4) is coated on the oxide film 12 and the source electrodes 14 to 15 to form the hard passivation layer 19. The hard passivation layer 19 is patterned to have a predetermined shape and has an opening 28 so that a large part of the source electrodes 14 to 15 can be exposed from the opening 28 of the hard passivation layer 19. The gate electrodes 16 to 17, which are not shown, are exposed from the openings 28 of the hard passivation layer 19 as well as the source electrodes 14 to 15. This will not be further described in detail.

Next, as shown in FIG. 4B, the under bump metal layer 23 is formed on the source electrodes 14 to 15 exposed from the opening 28 by the electroless plating utilizing the hard passivation layer 19 as a mask. In practice, the material constituting the under bump metal layer 23 may be nickel (Ni)/gold (Au) or nickel (Ni)/palladium (Pd)/gold (Au), but is not limited thereto. In terms of the gate electrodes 16 to 17 not shown the under bump metal layer 23 will similarly cover the gate electrodes 16 to 17.

Then, as shown in FIG. 4C, a passivation layer 18 is coated on the semiconductor substrate 11. More specifically, the method includes a step of forming an opening 20 by a lithography etching step after covering all regions of the upper surface of the semiconductor substrate 11 with a resin insulating film made of, for example, polyimide, and then performing heat hardening. The shape of the opening 20 is, for example, circular or slightly rectangular. Since the thickness of the passivation layer 18 is reduced, the heating time of the hardened passivation layer 18 can be shortened and the thermal stress acting on the semiconductor substrate 11 can be reduced.

Thereafter, as shown in FIG. 4D, a back electrode 22 is formed on the back surface of the semiconductor substrate 11. Specifically, after removing the oxide film 12 covering the back surface of the semiconductor substrate 11, the back surface of the semiconductor substrate 11 can be polished according to actual needs, wherein the back electrode 22 can then be formed on the semiconductor substrate 11 through a film formation method such as an electroless plating method.

After completing the above steps, the semiconductor device 10 shown in FIG. 1 is obtained by cutting the wafer through the above steps. As described above, since the cutting region 26 is formed at the periphery of the first and second transistors 30 and 31, and the cutting region 26 has removed the layers covering the upper surface of the semiconductor substrate 11, impacts that may adversely affect the passivation layer 18 and the like during the cutting stage may be suppressed.

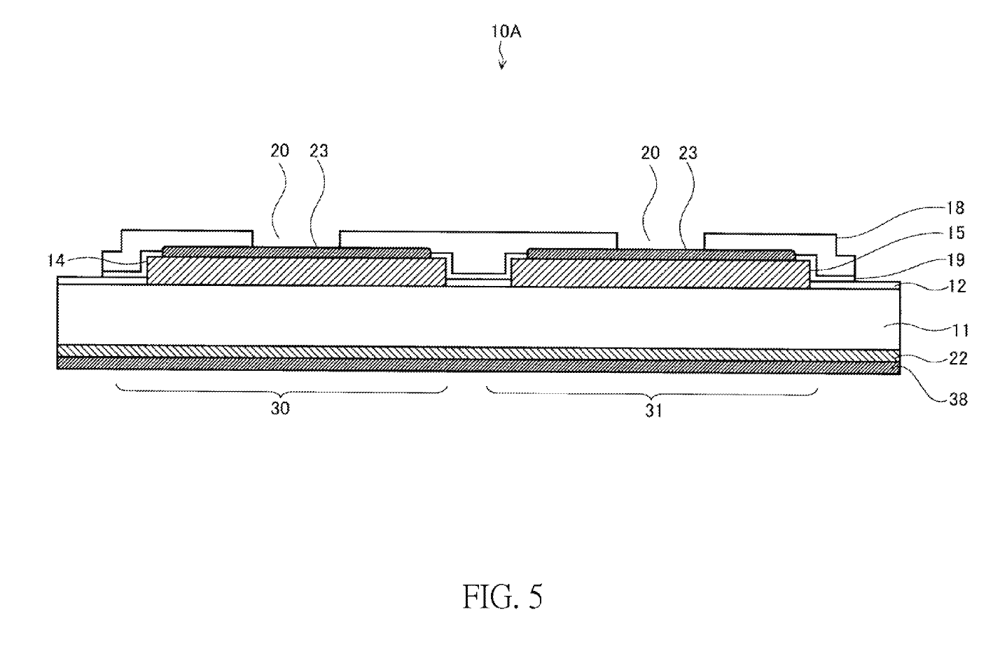

Please refer to FIG. 5. The basic structure of the semiconductor device 10A according to another embodiment shown in FIG. 5 is substantially the same as that of the semiconductor device 10 shown in FIG. 1, except that the semiconductor device 10A shown in FIG. 5 formed on the back side of the semiconductor substrate 11 below the back electrode 22 and is covered by a under bump metal layer 38 made of a metal material.

As shown in FIG. 5, the back electrode 22 connecting the drain electrodes of the first transistor 30 and the second transistor 31 covers almost the entire back surface of the semiconductor substrate 11, and the under bump metal layer 38 also covers almost the entire back surface of the semiconductor substrate 11. It should be noted that similar to the under bump metal layer 23 covering the source electrodes 14 to 15, the under bump metal layer 38 may be made of, for example, nickel (Ni)/gold (Au) or nickel (Ni)/palladium (Pd)/Gold (Au), and the thickness of the under bump metal layer 38 may be the same as that of the under bump metal layer 23, but is not limited thereto.

In this manner, since the under bump metal layer 38 almost covers the entire lower surface of the back electrode 22 so that the under bump metal layer 38 serves as a connection between the drain region of the first transistor 30 and the second transistor 31, spread resistance of the back electrode 22 can be reduced and power loss during operation of the semiconductor device 10A can also be decreased. In addition, since the thickness of the metal layer covering the back surface of the semiconductor substrate 11 is increased by the provision of the under bump metal layer 38, the amount of warping of the semiconductor substrate 11 when the semiconductor device 10A is affected by the temperature change can be reduced.

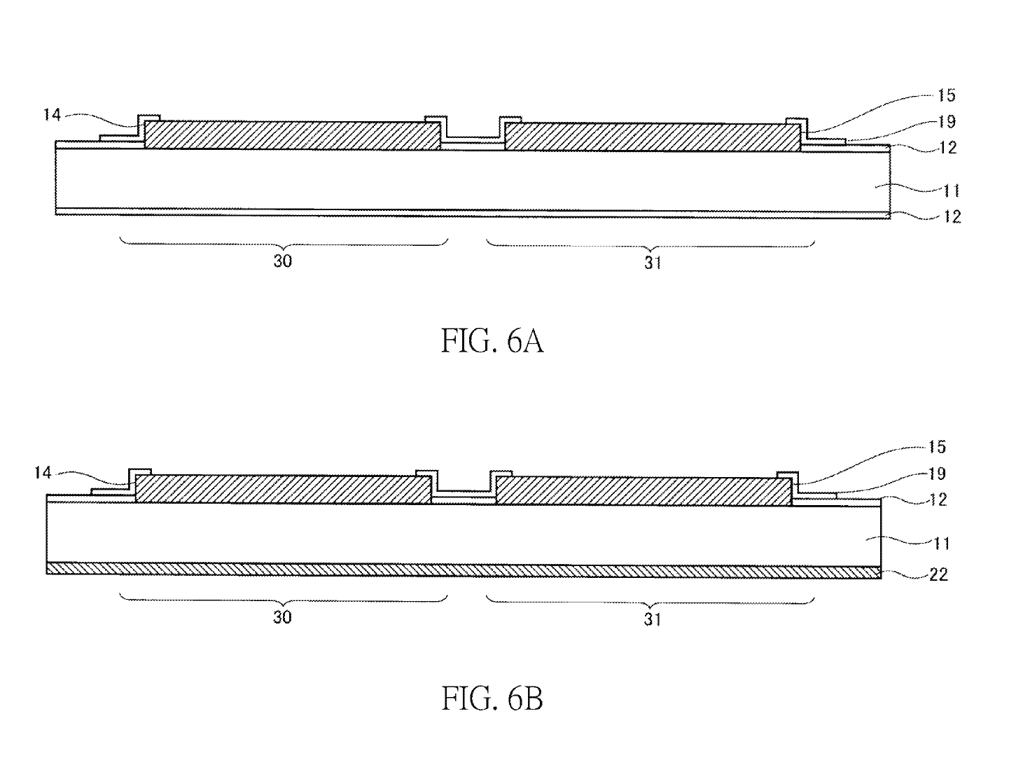

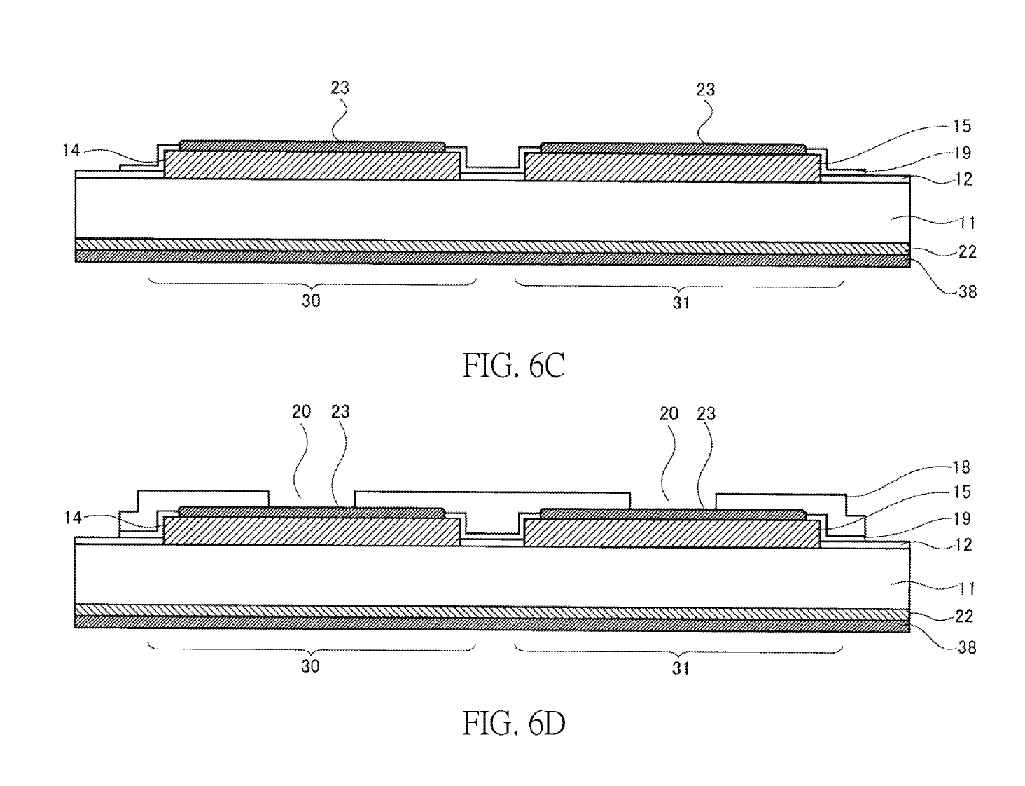

Next, please refer to FIGS. 6A to 6D. FIGS. 6A to 6D are cross-sectional views of each manufacturing step of the semiconductor device 10A described in order.

As shown in FIG. 6A, the oxide film 12, the source electrodes 14 to 15, and the hard passivation layer 19 are formed on the semiconductor substrate 11 on which the first and second transistors 30 and 31 are formed. Since the relevant steps are the same as those of FIG. 4A, they are not described in further detail here.

As shown in FIG. 6B, the back electrode 22 is formed on the back surface of the semiconductor substrate 11. Specifically, after removing the oxide film 12 covering the back surface of the semiconductor substrate 11 in FIG. 6A, the back electrode 22 may be formed on the back surface of the semiconductor substrate 11 by, for example, electroless plating, vapor deposition or sputtering. In practice, the material of the back electrode 22 may be the same as that of the source electrodes 14 to 15 formed on the semiconductor substrate 11, such as aluminum or an aluminum alloy or other metal materials.

As shown in FIG. 6C, in addition to covering the source electrodes 14 to 15 with the under bump metal layer 23, the under bump metal layer 38 is also simultaneously formed on the back surface electrode 22 on the back surface of the semiconductor substrate 11. In the present embodiment, the under bump metal layer 23 and the under bump metal layer 38 are formed by an electroless plating method using the same plating solution but are not limited thereto. The under bump metal layer 23 is selectively formed by using the hard passivation layer 19 formed on the semiconductor substrate 11 as a mask, and the under bump metal layer 38 is formed on the back surface of the semiconductor substrate 11 with no mask (Maskless) to form covering entirely. The under bump metal layers 23 and 38 may be formed by, for example, nickel (Ni)/gold (Au) or nickel (Ni)/palladium (Pd)/gold (Au), but are not limited thereto.

In the present step, since the under bump metal layer 23 for protecting the source electrodes 14 to 15 and the under bump metal layer 38 for reducing the spreading resistance are formed on the front and back surfaces of the semiconductor substrate 11 at the same time, it is possible to form the under bump metal layer 38 without any additional time and processes.

Next, as shown in FIG. 6D, the passivation layer 18 made of a resin insulating film is formed on the upper surface of the semiconductor substrate 11, and a passivation layer 18 is formed with the opening 20 to expose the bump down metal layer 23 that is in a circular shape.

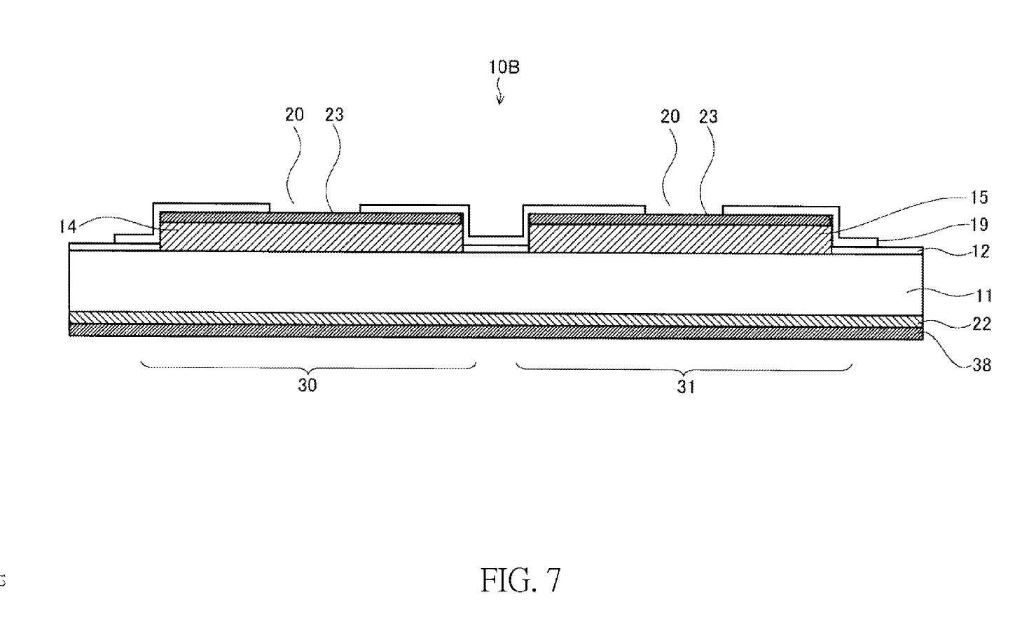

Also referring to FIG. 7, FIG. 7 illustrates another embodiments of the basic structure of the semiconductor device 10B that is substantially similar to the semiconductor device 10A, except that the semiconductor device 10B is formed on the source electrodes 14 to 15 of the semiconductor device 10B and a hard passivation layer 19 is formed on the upper surface of the under bump metal layer 23.

The upper surface of the source electrodes 14 to 15 is covered with the under bump metal layer 23, and the under bump metal layer 23 is covered with the hard passivation layer 19. Furthermore, the opening 20 is formed by forming a hard passivation layer 19 covering a portion of the under bump metal layer 23 in a circular shape, and the under bump metal layer 38 is exposed from the opening 20. Since only the hard passivation layer 19 is provided on the semiconductor device 10B as a layer covering the upper surface of the semiconductor substrate 11, the effect of reducing the structure of the semiconductor device can be obtained.

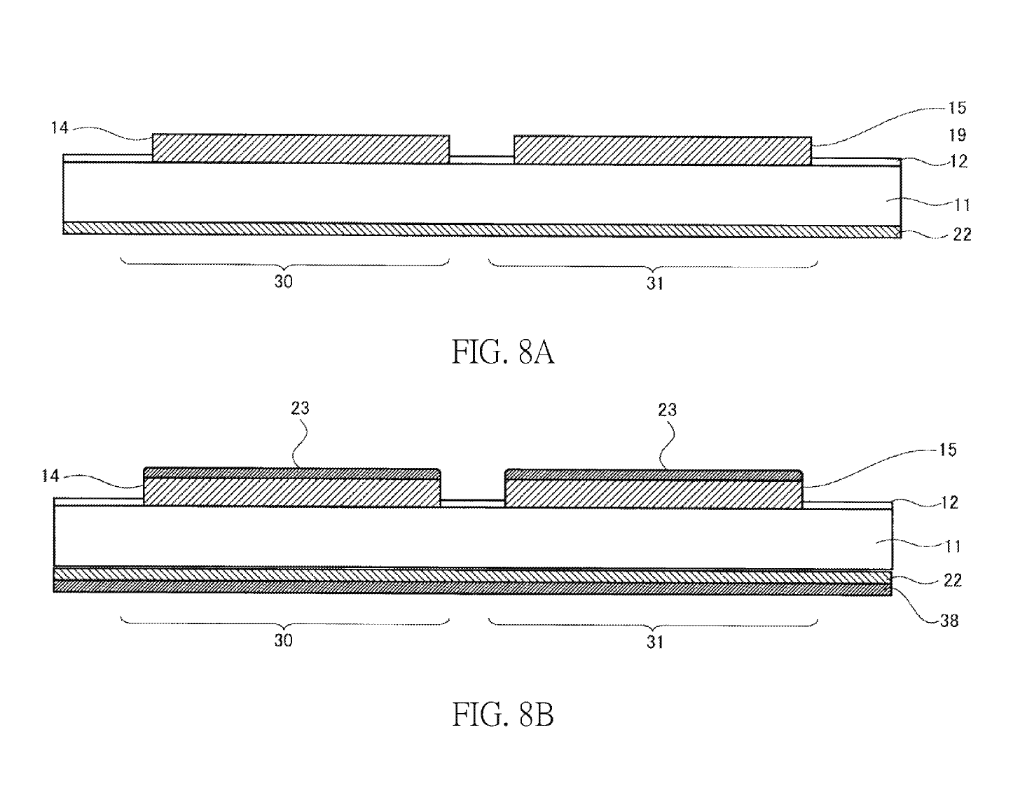

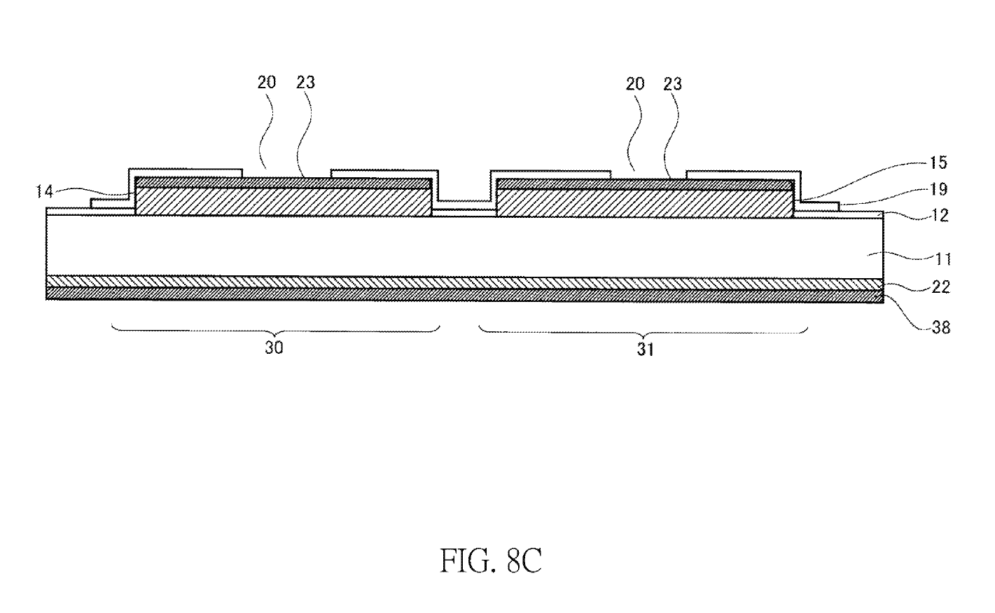

Next, please refer to FIGS. 8A to 8C. FIGS. 8A to 8C are cross-sectional views of each manufacturing step in order of the semiconductor device 10B.

As shown in FIG. 8A, firstly, the first transistor 30 and the second transistor 31 are formed on the semiconductor substrate 11, and source electrodes 14 to 15 are formed on the semiconductor substrate 11. In addition, the back electrode 22 covers the entire back surface of the semiconductor substrate 11. It should be noted that the source electrodes 14 to 15 are not covered with the passivation film in this step.

As shown in FIG. 8B, not only does the under bump metal layer 23 cover the source electrodes 14 to 15, but the under bump metal layer 38 also covers the back electrode 22. In the present embodiment, the under bump metal layers 23 and 38 may be formed by the same electroless plating solution, but are not limited thereto. The under bump metal layer 23 in FIG. 8B covers only the source electrodes 14 to 15, but may cover both the top and side surfaces of the source electrodes 14 to 15 at the same time. The under bump metal layers 23 and 38 may be formed by, for example, nickel (Ni)/gold (Au) or nickel (Ni)/palladium (Pd)/gold (Au), but are not limited thereto.

As shown in FIG. 8C, a hard passivation layer 19 made of, for example, silicon nitride (Si3N4), is formed on the semiconductor substrate 11, and the hard passivation layer 19 is formed with an opening 20 so that the under bump metal layer 23 is exposed by the opening 20 as a circle.

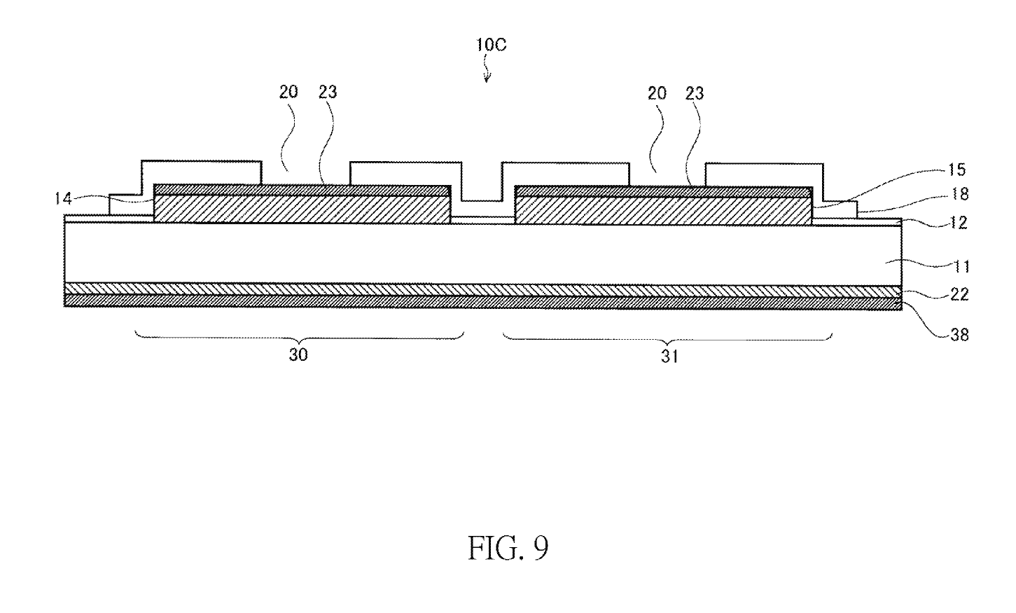

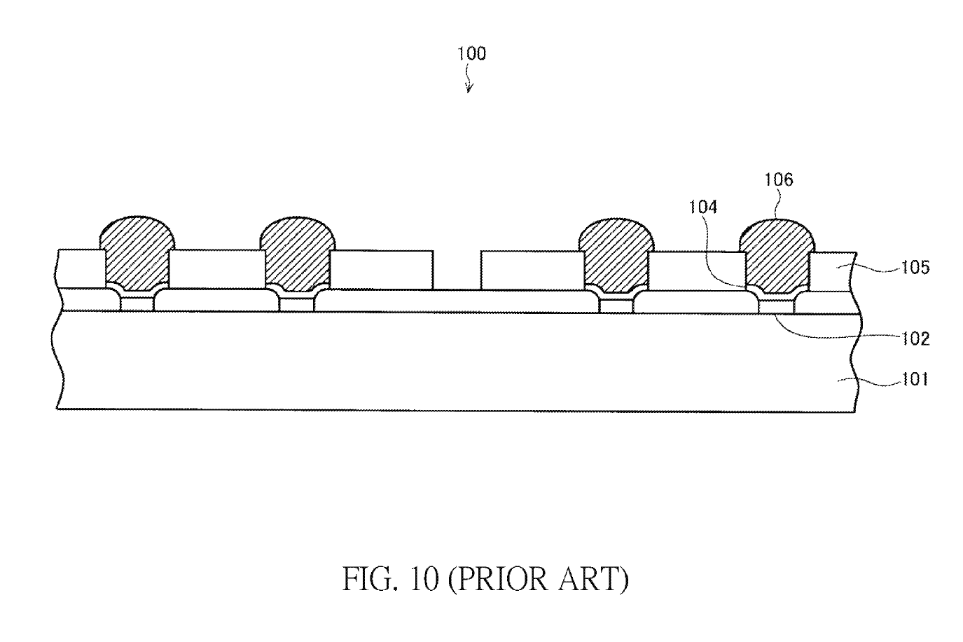

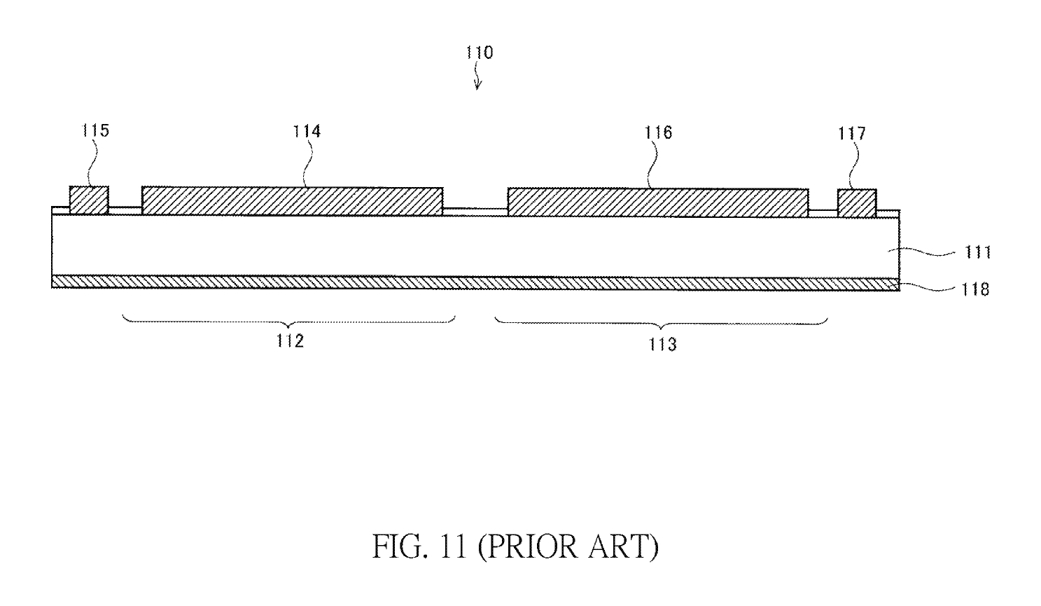

Please refer to FIG. 9. FIG. 9 shows another embodiment of the basic structure of the semiconductor device 10C that is similar to the semiconductor device 10B, except that the semiconductor device 10C substitutes the hard passivation layer 19 of the semiconductor device 10B for the passivation layer 18. As a result, the semiconductor substrate 10 can be covered with by a single passivation layer 18, thereby simplifying the structure of the semiconductor device 10C.

The manufacturing method of the semiconductor device 10C shown in FIG. 9 is substantially the same as the manufacturing method of the semiconductor device 10B shown in FIG. 8, except that the step of forming the passivation layer 18 replaces the formation of the hard passivation layer 19 in the semiconductor device 10B shown in FIG. 8C.

While the present invention has been described with reference to the different embodiments, the present invention is not limited thereto, and may be modified without departing from the spirit and scope of the present invention.

For example, in the above description, the semiconductor device 10 in which a plurality of transistors are formed is used as an embodiment of the semiconductor device. However, other semiconductor devices may actually be formed with a bipolar transistor, for example, Diodes, and the like can also be applied to the structure of the present invention.

What is claimed is:

1. A semiconductor device, comprising:
a semiconductor substrate having an active area;
an electrode formed on a first surface side of the semiconductor substrate;
a barrier film covering the electrode;
an insulation layer formed on the first surface side of the semiconductor substrate and covering the electrode; and
an opening formed in the insulation layer covering the electrode,
wherein an outer periphery of the barrier film is configured outsider than an outer periphery of the opening.

2. The semiconductor device of claim 1, wherein the insulation layer is formed by the organic insulating film or the resin insulating film.

3. A semiconductor device, comprising:
a semiconductor substrate having a first transistor and a second transistor;
a first gate electrode and a second gate electrode formed on a first surface side of the semiconductor substrate;
a first source electrode and a second source electrode formed on the first surface side of the semiconductor substrate;
a barrier film covering the first source electrode and the second source electrode;
a common drain electrode formed a second surface side of the semiconductor substrate;
an insulation layer formed on the first surface side of the semiconductor substrate and covering the first source electrode and the second source electrode; and
an opening formed in the insulation layer covering the first source electrode and the second source electrode,
wherein an outer periphery of the barrier film is configured outsider than an outer periphery of the opening.

4. The semiconductor device of claim 3, wherein the insulation layer comprises an inorganic insulating film covering the first surface side of the semiconductor substrate and a resin insulating film covering the inorganic insulating film, the inorganic insulting film covers the first source electrode and the second source electrode and has an exposed opening, the barrier film is formed on the first source electrode and the second source electrode at the exposed opening, the resin insulating film covers the first source electrode and the second source electrode and forms an opening.

5. The semiconductor device of claim 3, wherein the common drain electrode is covered by a metallic film and the metallic film is formed by the same type of metal of the barrier film.

6. The semiconductor device of claim 3, wherein the first source electrode is formed surrounding the first gate electrode and the second source electrode is formed surrounding the second gate electrode.

7. The semiconductor device of claim 3, wherein the insulation layer is formed by the organic insulating film or the resin insulating film.

8. The semiconductor device of claim 4, wherein the common drain electrode is covered by a metallic film and the metallic film is formed by the same type of metal of the barrier film.

9. The semiconductor device of claim 4, wherein the first source electrode is formed surrounding the first gate electrode and the second source electrode is formed surrounding the second gate electrode.

10. The semiconductor device of claim 5, wherein the first source electrode is formed surrounding the first gate electrode and the second source electrode is formed surrounding the second gate electrode.
